(19) United States
(12) Patent Application Publication
(10) Pub. No.: US 2025/0280570 A1
(43) Pub. Date: Sep. 4, 2025

(54) THIN FILM TRANSISTOR, MANUFACTURING METHOD THEREOF, AND DISPLAY APPARATUS COMPRISING THE SAME

(71) Applicant: LG Display Co., Ltd., Seoul (KR)

(72) Inventors: Yongjae KIM, Paju-si (KR); EunJi PARK, Paju-si (KR); KyungYun KANG, Paju-si (KR); Dongmin LIM, Paju-si (KR)

(73) Assignee: LG Display Co., Ltd., Seoul (KR)

(21) Appl. No.: 18/806,528

(22) Filed: Aug. 15, 2024

(30) Foreign Application Priority Data
Feb. 29, 2024 (KR) 10-2024-0030155

(51) Int. Cl. H01L 29/49; H01L 29/66; H01L 29/786; H10K 59/126

(52) U.S. Cl. CPC H10D 30/6739; H10D 30/6755; H10D 99/00; H10K 59/126

(57) ABSTRACT

A thin film transistor, a method of manufacturing the same, and a display apparatus including the same are discussed. The thin film transistor can include a base substrate, an active layer on the base substrate, a gate electrode spaced apart from the active layer and overlapping at least part of the active layer, a source electrode connected to the active layer, and a drain electrode spaced apart from the source electrode and connected to the active layer. Each of the gate electrode, the source electrode, and the drain electrode can include a first layer including a low-reflective material, a second layer disposed on the first layer and including a galvanic metal, a third layer disposed on the second layer, and a fourth layer disposed on the third layer. Further, the galvanic metal can have a higher electron affinity than the low-reflective material.

### CROSS-REFERENCE TO RELATED APPLICATIONS

This application claims priority to Korean Patent Application No. 10-2024-0030155 filed in the Republic of Korea on Feb. 29, 2024, the entire contents of which is hereby expressly incorporated by reference into the present application.

### BACKGROUND

### Field of the Invention

The present invention relates to a thin film transistor, a method of manufacturing the same, and a display apparatus including the same.

### Discussion of the Related Art

Nowadays, transistors are widely used as switching devices or driving devices in an electronic device field, especially in electronic devices such as a display apparatus, monitors, cell phones, among others. In particular, since a thin film transistor can be manufactured on a glass substrate or a plastic substrate, the transistor is widely used as a switching device of the display apparatus such as a liquid crystal display apparatus or an organic light emitting device among various displays.

Recently, research has been continuously conducted to implement a low reflection device in a field of transistors for use in the display apparatus, for example.

In addition, when a wet etching is performed after stacking low-reflective metals for a low-reflective implementation in the transistor for use in the display apparatus, due to a limitation of an etchant, there is a problem that a residual film of the low-reflective metals can undesirably remain after the wet etching, and research is continuously being conducted to solve this problem.

### SUMMARY OF THE DISCLOSURE

An embodiment of the present invention is to provide a thin film transistor in which a source electrode and a drain electrode include a first layer including a low-reflective material and a second layer including a galvanic metal on the first layer, so that no residual film is generated or remains during or after an etching process.

An embodiment of the present invention is to provide a thin film transistor having low resistance wiring characteristics while suppressing or preventing an increase in reflectance by adjusting a multilayer film structure having low reflection characteristics of a source electrode and a drain electrode.

Another configuration of the present invention is to provide a display apparatus including such a thin film transistor.

Another embodiment of the present invention is to provide a method of manufacturing such a thin film transistor.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor including a base substrate, an active layer on the base substrate, a gate electrode spaced apart from the active layer and overlapping at least part of the active layer, a source electrode connected to the active layer, and a drain electrode spaced apart from the source electrode and connected to the active layer, and each of the gate electrode, the source electrode, and the drain electrode includes a first layer including a low-reflective material; a second layer disposed on the first layer and including a galvanic metal; a third layer disposed on the second layer; and a fourth layer disposed on the third layer, and the galvanic metal has a higher electron affinity than the low-reflective material.

The first layer and the second layer can contact each other.

The low-reflective material can include a metal oxide (MOx) including an element M, and the element M can include a group 6B element.

The group 6B element can include at least one of chromium (Cr), molybdenum (Mo), and tungsten (W).

The galvanic metal can include at least one of Cu, Ag, Al, Mo, and Ti.

The third layer can include at least one selected from metal and transparent conductive oxide (TCO).

The metal can include a molybdenum-titanium alloy (MoTi).

The fourth layer can include a low resistance metal, and the low resistance metal can include at least one of Cu, Ag, Al, Mo, and Ti.

Each of the first layer of the source electrode, the first layer of the drain electrode, and the first layer of the gate electrode can have a thickness of 200 to 600 Å.

Each of the source electrode and the drain electrode is connected to the active layer through a first contact portion and a second contact portion, and the first contact portion and the second contact portion can include a first section and a second section on the first section of the first contact portion and the second contact portion, respectively.

The first section and the second section of the first contact portion can be formed to extend from the third layer and the fourth layer of the source electrode, and the first section and the second section of the second contact portion can be formed to extend from the third layer and the fourth layer of the drain electrode.

The active layer can include a channel area overlapping the gate electrode, a source area connected to one side of the channel area, and a drain area connected to the other side of the channel area, and the first contact portion can be disposed on the source area and the second contact portion can be disposed on the drain area.

A light blocking layer on the base substrate can be further included, and the source electrode can be connected to the light blocking layer through a third contact portion.

The light blocking layer can include a first layer and a second layer on the first layer of the light blocking layer, the first layer of the light blocking layer can include a low reflective material, and the second layer of the light blocking layer can include a low resistance metal.

The third contact portion can include a first section and a second section on the first section of the third contact portion, the first section of the third contact portion can be formed to extend from the third layer of the source electrode, and the second section of the third contact portion can be formed to extend from the fourth layer of the source electrode.

Another configuration of the present invention provides a display apparatus including the thin film transistor.

Another embodiment of the present invention provides a manufacturing method of the thin film transistor including forming a light blocking layer and an active layer on the base substrate; forming a low-reflective material layer on the active layer; forming a galvanic metal material layer on the low-reflective material layer; forming a photoresist material layer on the galvanic metal material layer and etching to expose a portion of the light blocking layer and a portion of the active layer; forming a first metal material layer on the galvanic metal material layer; and forming a second metal material layer on the first metal material layer; and forming a gate electrode, a source electrode, and a drain electrode by simultaneously etching the low-reflective material layer, the galvanic metal material layer, the first metal material layer and the second metal material layer.

The low-reflective material layer can include a low-reflective material, the low-reflective material can include a metal oxide (MOx) containing an element M, and the element M can include a group 6B element.

The galvanic metal material layer can include a galvanic metal, and the galvanic metal can include at least one of Cu, Ag, Al, Mo, and Ti.

The first metal material layer can include at least one selected from metal and transparent conductive oxide (TCO), the second metal material layer can include a low resistance metal, and the low resistance metal can include at least one of Cu, Ag, Al, Mo, and Ti.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view of a thin film transistor according to an embodiment of the present invention.

FIG. 2 is a cross-sectional view of a thin film transistor according to another embodiment of the present invention.

FIGS. 3A to 3H are process diagrams showing a process of manufacturing a thin film transistor according to an embodiment of the present invention.

FIG. 4 is a schematic view of a display apparatus according to an embodiment of the present invention.

FIG. 5 is a circuit diagram of any one pixel of FIG. 4.

### DETAILED DESCRIPTION OF THE EMBODIMENTS

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion can be added unless ‘only˜’ is used. The terms of a singular form can include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions can be disposed between two other portions unless ‘just’ or ‘direct’ is used.

Spatially relative terms such as “below”, “beneath”, “lower”, “above”, and “upper” can be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device can be arranged “above” another device. Therefore, an exemplary term “below or beneath” can include “below or beneath” and “above” orientations. Likewise, an exemplary term “above” or “on” can include “above” and “below or beneath” orientations.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” can include all combinations of two or more elements selected from the first, second and third elements as well as each element of the first, second and third elements.

It should be understood that the term “can” fully encompasses all the meanings and coverages of the term “may.”

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode can be interchanged. The source electrode can be the drain electrode and vice versa. In addition, the source electrode of any one embodiment can be a drain electrode in another embodiment, and the drain electrode of any one embodiment can be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area can be the source electrode, and the drain area can be the drain electrode. In addition, the source area can be the drain electrode, and the drain area can be the source electrode.

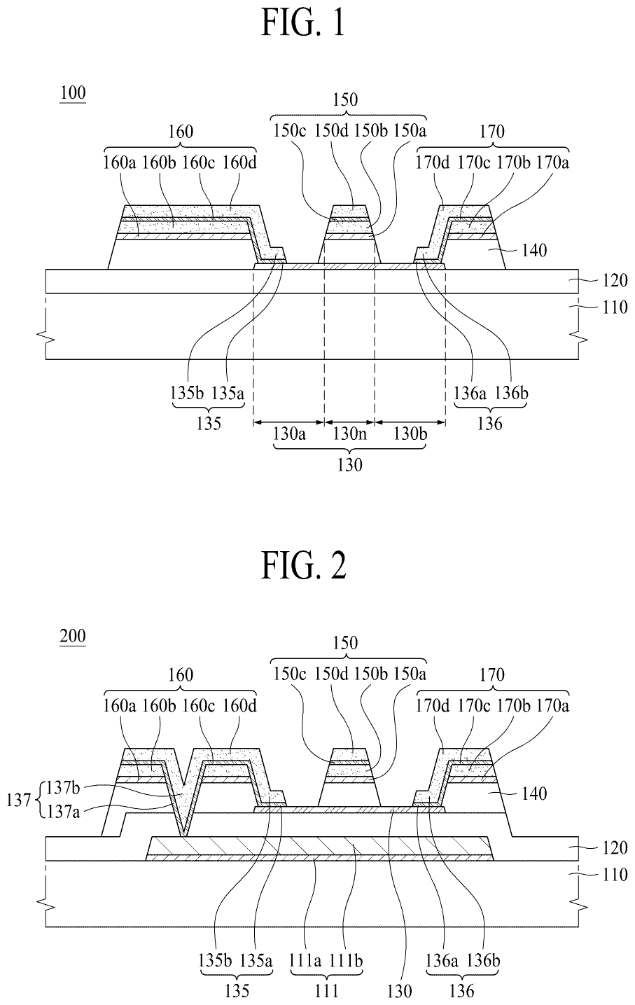

FIG. 1 is a cross-sectional view of a thin film transistor 100 according to an embodiment of the present invention. FIG. 2 is a cross-sectional view of a thin film transistor 200 according to another embodiment of the present invention. All the components of the thin film transistor according to all embodiments are operationally coupled and configured.

Specifically, referring to FIG. 1, the buffer layer 120 on the base substrate 110, the active layer 130 on the buffer layer 120, the gate electrode 150 spaced apart from the active layer 130 to at least partially overlap the active layer 130, the source electrode 160 and the drain electrode 170 connected to the active layer 130 are disposed.

According to an embodiment of the present invention, the thin film transistor 100 can further include a base substrate 110. Referring to FIG. 1, the buffer layer 120 is disposed on the base substrate 110.

According to an embodiment of the present invention, the thin film transistor 100 can further include a gate insulating layer 140. Referring to FIG. 1, the gate insulating layer 140 is disposed on the active layer 130. Specifically, the gate insulating layer 140 is disposed between the active layer 130 and the gate electrode 150.

According to an embodiment of the present invention, another layer of the thin film transistor 100 can be additionally disposed on the gate electrode 150. In detail, the thin film transistor 100 can further include one or more additional layers 180 that can cover the thin film transistor 100, such as an interlayer insulating layer. The gate electrode 150 can be disposed between the gate insulating layer 140 and the interlayer insulating layer. But embodiments of the present disclosure are not limited thereto.

Hereinafter, components of the thin film transistor 100 according to an embodiment of the present invention will be described in more detail.

Glass or plastic can be used for the base substrate 110. Transparent plastic having flexible characteristics, for example, polyimide, can be used as plastic.

When the polyimide is used as the base substrate 110, considering that a high-temperature deposition process is performed on the base substrate 110, a heat-resistant polyimide capable of withstanding a high temperature can be used. In this case, in order to form a thin film transistor, processes such as deposition, etching, and the like can be performed in a state in which the polyimide substrate is disposed on the carrier substrate made of a high-durable material such as glass.

A buffer layer 120 can be disposed on the base substrate 110.

The buffer layer 120 is formed on the base substrate 110 and can be formed of an inorganic material or an organic material. But embodiments of the present disclosure are not limited thereto. For example, an insulating oxide such as silicon oxide (SiOx), silicon nitride (SiNx), silicon oxynitride (SiON), aluminum oxide (Al₂O₃).

The buffer layer 120 protects the active layer 130 by blocking impurities such as moisture and oxygen introduced from the base substrate 110, serves to flatten the upper portion of the base substrate 110, and can be formed as a single layer or a plurality of layers.

Referring to FIGS. 1 and 2, an active layer 130 can be disposed on the buffer layer 120.

The active layer 130 can include a channel area 130n, a source area 130a, and a drain area 130b.

The channel area 130n overlaps the gate electrode 150. The channel area 130n serves as a channel of the thin film transistor 100.

Specifically, the active layer 130 can include a channel area 130n overlapping the gate electrode 150, a source area 130a connected to one side of the channel area 130n, and a drain area 130b connected to the other side of the channel area 130n without overlapping the gate electrode 150.

According to an embodiment of the present invention, the source area 130a and the drain area 130b are spaced apart from each other with the channel area 130n interposed therebetween.

According to a configuration of the present invention, the active layer 130 can be formed of a semiconductor material. The active layer 130 can include an oxide semiconductor material.

The oxide semiconductor material can include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, an embodiment of the present invention is not limited thereto, and the active layer 130 can be made of another oxide semiconductor material known in the art.

The source area 130a and the drain area 130b can be formed by selective conductorization with respect to the active layer 130 made of a semiconductor material. According to an embodiment of the present invention, imparting conductivity to a specific portion of the active layer 130 so that it can function as a conductor is referred to as selective conductorization. By this selective conductorization, a portion to which conductivity is imparted is conductorized, and a portion to which conductivity is not imparted is not conductorized.

Although a configuration in which the active layer 130 is formed of a single layer is disclosed in FIG. 1, a configuration of the present invention is not limited thereto. The active layer 130 can have a single layer structure or a multilayer structure.

According to an embodiment of the present invention, the channel area 130n, the source area 130a, and the drain area 130b of the active layer 130 can be integrally formed, and the active layer 130 can have a constant thickness. Specifically, the active layer 130 can have substantially the same thickness.

The gate insulating layer 140 is disposed on the active layer 130. The gate insulating layer 140 protects the channel area 130n. Specifically, the gate insulating layer 140 is disposed between the active layer 130 and the gate electrode 150.

The gate insulating layer 140 has insulating properties. The gate insulating layer 140 can include at least one of silicon oxide, silicon nitride, and metal-based oxide, for example. But embodiments of the present disclosure are not limited thereto. The gate insulating layer 140 can have a single layer structure or a multilayer structure.

The gate electrode 150 is disposed on the gate insulating layer 140. The gate electrode 150 overlaps the channel area 130n of the active layer 130.

According to an embodiment of the present invention, the gate electrode 150 can include a first layer 150a, a second layer 150b on the first layer 150a, a third layer 150c on the second layer 150b, and a fourth layer 150d on the third layer 150c.

Specifically, the first layer 150a of the gate electrode 150 includes a low reflective material. For example, the low reflective material can include a metal oxide (MOx) containing the element M. In this case, the element M can include a group 6B element. But embodiments of the present disclosure are not limited thereto.

For example, the group 6B element can include at least one of chromium (Cr), molybdenum (Mo), and tungsten (W).

The second layer 150b of the gate electrode 150 includes a galvanic metal. For example, the galvanic metal can include at least one of Cu, Ag, Al, Mo, and Ti. But embodiments of the present disclosure are not limited thereto.

In this case, galvanic metal has higher electron affinity than low reflective material.

If the electron affinity of the galvanic metal is greater than the electron affinity of the low reflective material, when wet etching is performed to form a contact hole, through a galvanic reaction, as the galvanic metal disposed at the top absorbs electrons, no residue of the first layer 150a containing a low-reflection material is left, and a neatly shaped contact hole can be created.

On the other hand, when the second layer 150b including the galvanic metal is not disposed on the first layer 150a, a low-reflective material layer including a low-reflective material is formed, and then wet etching can be performed to immediately form the contact hole. In this case, a galvanic reaction does not occur, and a residual film of the low-reflective material layer can be formed due to limitations of the etchant. Subsequently, when dry etching is continuously performed, a spark-shaped residual film can be formed. As a result, such a residual film can cause a defect or a defect of a disconnection.

In addition, if the electron affinity of the galvanic metal is less than the electron affinity of the low-reflective material, the galvanic reaction may not proceed effectively, and a residual film of the low-reflective material layer can be formed due to the limitation of the etchant. Subsequently, when dry etching is continuously performed, a spark-shaped residual film can occur. As a result, such a residual film can cause a defect or a defect in disconnection.

According to an embodiment of the present invention, when the first layer 150a of the gate electrode 150 includes a low-reflective material and the second layer 150b includes a galvanic metal, the first layer 150a can reflect a part of light incident from the outside and transmit or absorb the remaining part of the light. In addition, the remaining light that has passed through transmission or absorption in the first layer 150a can be reflected on the surface of the second layer 150b of the gate electrode 150. Accordingly, the light reflected from the first layer 150a and the second layer 150b meet on the surface of the first layer 150a in a state of being in opposite phases to each other, causing destructive interference. As a result, an increase in reflectance due to external light in the display apparatus can be reduced or prevented.

The third layer 150c of the gate electrode 150 can include at least one selected from a metal and a transparent conductive oxide (TCO). For example, the metal of the third layer 150c can include molybdenum-titanium alloy (MoTi). But embodiments of the present disclosure are not limited thereto.

The fourth layer 150d of the gate electrode 150 can include a low resistance metal. For example, the low resistance metal can include at least one of Cu, Ag, Al, Mo, and Ti. But embodiments of the present disclosure are not limited thereto.

In addition, when the fourth layer 150d of the gate electrode 150 includes a low-resistance metal material (a low-resistance metal material) such as a low-resistance metal, the gate electrode 150 can serve as a wiring having low resistance characteristics. In other words, the gate electrode 150 can serve as a wiring having a low resistance.

For example, in the gate electrode 150 according to the present invention, the first layer 150a includes a low-reflective material and the second layer 150b includes a galvanic metal, so that the reflectance of light incident from the outside can be reduced, and the problem of residual film occurring can be suppressed or prevented, and the fourth layer 150d includes a low-resistance metal, thereby lowering the resistance of the gate electrode 150 and thus serving as a wiring.

According to an embodiment of the present invention, the gate insulating layer 140 can be patterned by etching using the gate electrode 150 as a mask, and in this process, the active layer 130 can be selectively conductorization to form the source area 130a and the drain area 130b. Specifically, according to an embodiment of the present invention, a region of the active layer 130 overlapping the gate electrode 150 is not conductorized to become a channel area 130n having semiconductor characteristics, and a region that does not overlap the gate electrode 150 can be conductorized to become the source area 130a and the drain area 130b.

According to an embodiment of the present invention, the thin film transistor 100 can include a source electrode 160 and a drain electrode 170. Positions of the source electrode 160 and the drain electrode 170 can be exchanged with each other. However, an embodiment of the present invention is not limited thereto, and the source area 130a and the drain area 130b can serve as source electrodes and drain electrodes, respectively.

Referring to FIG. 1, each of the source electrode 160 and the drain electrode 170 can be connected to the active layer 130 through a contact hole. Specifically, the source electrode 160 can be in contact with the source area 130a through a contact hole. The drain electrode 170 can be spaced apart from the source electrode 160 to be in contact with the drain area 130b through a contact hole. More specifically, the source electrode 160 and the drain electrode 170 can be connected to the active layer 130 through the first contact portion 135 and the second contact portion 136, respectively.

Hereinafter, the source electrode 160, the drain electrode 170, the first contact portion 135, and the second contact portion 136 according to an embodiment of the present invention will be described in detail.

The source electrode 160 is connected to the active layer 130, and the drain electrode 170 is spaced apart from the source electrode 160, and is connected to the active layer 130.

The source electrode 160 and the drain electrode 170 include first layers 160a and 170a, second layers 160b and 170b on first layers 160a and 170a, third layers 160c and 170c on second layers 160b and 170b, and fourth layers 160d and 170c on third layers 160c and 170c, respectively.

In this case, the first layers 150a, 160a, and 170a of the gate electrode 150, the source electrode 160, and the drain electrode 170 can be disposed on the same layer. Specifically, referring to FIG. 1, the first layers 150a, 160a, and 170a of the gate electrode 150, the source electrode 160, and the drain electrode 170 are disposed on the gate insulating layer 140. More specifically, the first layers 150a, 160a, and 170a of the gate electrode 150, the source electrode 160, and the drain electrode 170 can be formed of the same material by the same process. However, an embodiment of the present invention is not limited thereto, and can be disposed on different layers.

According to an embodiment of the present invention, the first layers 160a and 170a of the source electrode 160 and the drain electrode 170 include a low reflective material. For example, the low reflective material can include a metal oxide (MOx) containing an element M. In this case, the element M can include a group 6B element. But embodiments of the present disclosure are not limited thereto.

For example, the group 6B element can include at least one of chromium (Cr), molybdenum (Mo), and tungsten (W). But embodiments of the present disclosure are not limited thereto.

The second layers 160b and 170b of the source electrode 160 and the drain electrode 170 include a galvanic metal. For example, the galvanic metal can include at least one of Cu, Ag, Al, Mo, and Ti. But embodiments of the present disclosure are not limited thereto.

In this case, galvanic metal has higher electron affinity than low reflective material.

If the electron affinity of the galvanic metal is greater than the electron affinity of the low reflective material, when wet etching is performed to form a contact hole, through a galvanic reaction, the galvanic metal placed on top absorbs electrons, leaving no residue on the first layer (160a, 170a) containing a low-reflection material is left, and a neatly shaped contact hole can be created.

On the other hand, when the second layers 160b and 170b including the galvanic metal are not disposed on the first layers 160a and 170a, a low-reflective material layer including a low-reflective material is formed, and then a wet etch can be performed to immediately form the contact hole. In this case, a galvanic reaction may not occur, and a residual film of the low-reflective material layer can be formed due to limitations of the etchant. Subsequently, when dry etching is continuously performed, a spark-shaped residual film can be formed. As a result, such a residual film can cause a defect and a defect in disconnection.

In addition, if the electron affinity of the galvanic metal is less than the electron affinity of the low-reflective material, the galvanic reaction may not proceed effectively, and a residual film of the low-reflective material layer can be formed due to the limitation of the etchant. Subsequently, when dry etching is continuously performed, a spark-shaped residual film can occur. As a result, such a residual film can cause a defect or a defect in disconnection.

According to an embodiment of the present invention, when the first layers 160a and 170a of the source electrode 160 and the drain electrode 170 include a low-reflective material and the second layers 160b and 170b include a galvanic metal, the first layers 160a and 170a can reflect a part of light incident from the outside and transmit or absorb the remaining part of the light. Further, the remaining light that has been transmitted or absorbed from the first layers 160a and 170a can be reflected from the surfaces of the second layers 160b and 170b of the source electrode 160 and the drain electrode 170. Accordingly, the light reflected from the first layers 160a and 170b meets on the surfaces of the first layers 160a and 170a in a state of being opposite phases to each other, causing destructive interference. As a result, an increase in reflectance due to external light in the display apparatus can be reduced or prevented.

The third layers 160c and 170c of the source electrode 160 and the drain electrode 170 can include at least one selected from a metal and a transparent conductive oxide (TCO). For example, the metal of the third layers 160c and 170c can include molybdenum-titanium alloy (MoTi). But embodiments of the present disclosure are not limited thereto.

The fourth layers 160d and 170d of the source electrode 160 and the drain electrode 170 can include a low resistance metal. For example, the low resistance metal can include at least one of Cu, Ag, Al, Mo, and Ti. But embodiments of the present disclosure are not limited thereto.

In addition, when the fourth layers 160d and 170d of the source electrode 160 and the drain electrode 170 include a low-resistance metal material (a low-resistance metal material) such as a low-resistance metal, the source electrode 160 and the drain electrode 170 can serve as a wiring having a low resistance characteristic. In other words, the source electrode 160 and the drain electrode 170 can serve as a wiring having a low resistance.

For example, in the source electrode 160 and drain electrode 170 according to the present invention, the first layers 160a and 170a include a low-reflective material, and the second layers 160b and 170b include a galvanic metal, so that the reflectance of light incident from the outside can be reduced, and the problem of residual film generation can be suppressed or prevented, and the fourth layers 160d and 170d include a low-resistance metal, thereby lowering the resistance of the source electrode 160 and the drain electrode 170, thereby serving as a wiring. But embodiments of the present disclosure are not limited thereto.

According to an embodiment of the present invention, the first contact portion 135 can include a first section 135a and a second section 135b on the first section 135a. The second contact portion 136 can include a first section 136a and a second section 136b on the first section 136a.

In this case, the source electrode 160 and the drain electrode 170 can be connected to the active layer 130 through the first contact portion 135 and the second contact portion 136, respectively.

Specifically, the first section 135a and the second section 135b of the first contact portion 135 are in contact with the third layer 160c and the fourth layer 160d of the source electrode 160, respectively. More specifically, the first section 135a and the second section 135b of the first contact portion 135 are formed to extend from the third layer 160c and the fourth layer 160d of the source electrode 160.

Referring to FIGS. 1 and 2, the first section 135a and the second section 135b of the first contact portion 135 can be formed by the same process as the third layer 160c and the fourth layer 160d of the source electrode 160 and can be integrally formed.

The first section 136a and the second section 136b of the second contact portion 136 are in contact with the third layer 170c and the fourth layer 170d of the drain electrode 170, respectively. More specifically, the first section 136a and the second section 136b of the second contact portion 136 are formed to extend from the third layer 170c and the fourth layer 170d of the drain electrode 170.

Referring to FIGS. 1 and 2, the first section 136a and the second section 136b of the second contact portion 136 can be formed by the same process as the third layer 170c and the fourth layer 170d of the drain electrode 170 and can be integrally formed.

Specifically, the first contact portion 135 and the second contact portion 136 can be disposed on the source area 130a and the drain area 130b of the active layer 130, respectively. In FIGS. 1 and 2, a structure in which the third layer 160c of the source electrode 160 is connected to the source area 130a through the first contact portion 135 is shown, and a structure in which the third layer 170c of the drain electrode 170 is connected to the drain area 130b through the second contact portion 136 is shown.

According to an embodiment of the present invention, the first layers 135a and 136a of the first contact portion 135 and the second contact portion 136 can include at least one selected from a metal and a transparent conductive oxide (TCO). Specifically, the metal can include a molybdenum-titanium alloy (MoTi), and the transparent conductive oxide (TCO) can include ITO (InSnO), IZO (InZnO), IO (InO), TO (SnO), and ZO (ZnO). However, an embodiment of the present invention is not limited thereto, and the first layers 135a and 136a of the first contact portion 135 and the second contact portion 136 can include an oxide having conductivity.

The first layers 135a and 136a of the first contact portion 135 and the second contact portion 136 can have reducibility. The active layer 130 can be selectively conductorized by the first layers 135a and 136a of the first contact portion 135 and the second contact portion 136. According to an embodiment of the present invention, the source area 130a and the drain area 130b are in contact with the first layers 135a and 136a of the first contact portion 135 and the second contact portion 136, respectively. A region of the active layer 130, which is in contact with the first layers 135a and 136a of the first contact portion 135 and 136a of the second contact portion 136, is conductorized to form a source area 130a and a drain area 130b, respectively.

Specifically, according to an embodiment of the present invention, portions of the active layer 130 in contact with the first layers 135a and 136a of the first contact portion 135 and the second contact portion 136 can be reduced, respectively, to form the source area 130a and the drain area 130b.

For example, when a part of the active layer 130 which contacts and overlaps the first layers 135a and 136a of the first contact portion 135 and the second contact portion 136 is reduced, an oxygen vacuum occurs in the active layer 130, and accordingly, the active layer 130 can be selectively conductorization. By the selective reduction of the active layer 130, the source area 130a and the drain area 130b can be formed. But embodiments of the present disclosure are not limited thereto.

According to an embodiment of the present invention, the first layers 150a, 160a, and 170a of the gate electrode 150, the source electrode 160, and the drain electrode 170 can each have a thickness of 200 to 600 Å. In this case, when the first layers 150a, 160a, and 170a of the gate electrode 150, the source electrode 160, and the drain electrode 170 have a thickness of 200 to 600 Å, the first layers 150a, 160a, and 170a can be efficiently stacked on the gate insulating layer 140 and at the same time have excellent low reflection characteristics.

On the other hand, when the first layers 150a, 160a, and 170a of the gate electrode 150, the source electrode 160, and the drain electrode 170 have a thickness of less than 200 Å, the first layers 150a, 160a, and 170a are not sufficiently stacked, and thus the thin film transistor 100 may not have excellent low reflection characteristics.

In addition, when the first layers 150a, 160a, and 170a of the gate electrode 150, the source electrode 160, and the drain electrode 170 have a thickness greater than 600 Å, the distance between the gate electrode 150 and the active layer 130 can become excessively distant, resulting in a problem in that the influence of the electric field generated in the gate electrode 150 is excessively reduced. In addition, when the first layers 150a, 160a, and 170a have a thickness greater than 600 Å, the thickness of the first layers 150a, 160a, and 170a can become excessively thick, resulting in a step difference between each layer, resulting in a problem in that a seam occurs in the step difference.

Referring to FIG. 2, the thin film transistor 200 according to an embodiment of the present invention can further include a light blocking layer 111. FIG. 2 shows the structure in which the light blocking layer 111 is disposed on the base substrate 110.

According to an embodiment of the present invention, the source electrode 160 can be connected to the light blocking layer 111 through the third contact portion 137. FIG. 2 shows a structure in which the source electrode 160 and the light blocking layer 111 are connected through the third contact portion 137.

According to an embodiment of the present invention, the light blocking layer 111 can include a first layer 111a and a second layer 111b on the first layer 111a. In detail, the first layer 111a of the light blocking layer 111 can include a low reflective material, and the second layer 111b can include a low resistance metal. For example, the low reflective material can include a metal oxide (MOx) containing the element M. In this case, the element M can include a group 6B element. For example, the group 6B element can include at least one of chromium (Cr), molybdenum (Mo), and tungsten (W). The low resistance metal can include at least one of Cu, Ag, Al, Mo, and Ti. But embodiments of the present disclosure are not limited thereto.

FIG. 2 further includes a light blocking layer 111 compared to FIG. 1, and even in this case, the first layer 111a of the light blocking layer 111 can reflect a part of light incident from the outside, and transmit or absorb the remaining part of the light. Further, the remaining light that has passed through transmission or absorption in the first layer 111a can be reflected on the surface of the second layer 111b of the light blocking layer 111. Accordingly, the light reflected from the first layer 111a and the second layer 111b meet on the surface of the first layer 111a in a state of being opposite phases to each other, causing destructive interference. As a result, an increase in reflectance due to external light in the display apparatus can be reduced or prevented.

According to an embodiment of the present invention, the third contact portion 137 includes a first section 137a and a second section 137b on the first section 137a.

The third contact portion 137 refers to an area formed inside the hole, as compared to the source electrode 160. Specifically, it refers to an area formed in the thin film transistor manufacturing process and surrounded by the buffer layer 120, the gate insulating layer 140, the first layer 160a and the second layer 160b of the source electrode 160.

In this case, the first section 137a of the third contact portion 137 can include at least one selected from a metal and a transparent conductive oxide (TCO), and the second section 137b can include a low resistance metal. Specifically, the first section 137a of the third contact portion 137 can be formed of the same material as those of the third layers 150c, 160c, and 170c of the gate electrode 150, the source electrode 160, and the drain electrode 170, and the second section 137b of the third contact portion 137 can be formed of the same process as those of the gate electrode 150, the source electrode 160, and the fourth layers 150d, 160d, and 170d of the drain electrode 170.

According to an embodiment of the present invention, the first section 137a of the third contact portion 137 can be integrally formed with the first layer 160a of the source electrode 160, and the second section 137b of the third contact portion 137 can be integrally formed with the second layer 160b of the source electrode 160.

With reference to FIGS. 1 and 2, each of the gate electrode 150, the source electrode 160 and the drain electrode 170 can be provided with various layers, including the first through fourth layers 150a through 150d for the gate electrode 150, the first through fourth layers 160a through 160d for the source electrode 160 and the first through fourth layers 170a through 170d for the drain electrode 170. But embodiments of the present disclosure are not limited thereto. For example, the gate electrode 150, the source electrode 160 and the drain electrode 170 can variously have less than the four layers, so that the gate electrode 150, the source electrode 160 and the drain electrode 170 can each have the first layer and the second layer, and can have one of the third layer and the fourth layer in various embodiments of the present disclosure. For example, the second layer can be disposed between the first layer and the third layer or the fourth layer for one or more of the gate electrode 150, the source electrode 160 and the drain electrode 170. Additional layers can be disclosed between the various layers of the gate electrode 150, the source electrode 160 and/or the drain electrode 170.

Further, various layers of the gate electrode 150, the source electrode 160 and/or the drain electrode 170 can be respectively coplanar. For example, the first through fourth layers 150a through 150d of the gate electrode 150 can be respectively coplanar with the first through fourth layers 160a through 160d of the source electrode 160 and/or respectively coplanar with the first through fourth layers 170a through 170d of the drain electrode 170. Accordingly, the first layer 150a, the first layer 160a and/or the first layer 170a can be coplanar, the second layer 150b, the second layer 160b and/or the second layer 170b can be coplanar, the third layer 150c, the third layer 160c and/or the third layer 170c can be coplanar, and/or the fourth layer 150d, the fourth layer 160d and/or the fourth layer 170d can be coplanar, but embodiments of the present disclosure are not limited thereto. For example, some layers of the gate electrode 150, the source electrode 160 and/or the drain electrode 170 can be respectively coplanar, while other layers thereof can be not coplanar. But embodiments of the present disclosure are not limited thereto.

Furthermore, the thicknesses of the gate insulating layer 140 under or below the gate electrode 150, the source electrode 160 and/or the drain electrode 170 can be the same or can be different. For example, a thickness of the gate insulating layer 140 directly below the source electrode 160 can be different from a thickness of the gate insulating layer 140 directly below the gate electrode 150 and/or a thickness of the gate insulating layer 140 directly below the drain electrode 170. For example, the thickness of the gate insulating layer 140 directly below the source electrode 160 and the thickness of the gate insulating layer 140 directly below the drain electrode 170 can be the same, but different from the thickness of the gate insulating layer 140 directly below the gate electrode 150. But embodiments of the present disclosure are not limited thereto.

Additionally, when the thicknesses of the gate insulating layer 140 under or below the gate electrode 150, the source electrode 160 and/or the drain electrode 170 are the same or different, uppermost surfaces of the gate insulating layer 140 under or below the gate electrode 150, the source electrode 160 and/or the drain electrode 170, respectively, can be coplanar or can be of different height. For example, the uppermost surface of the gate insulating layer 140 under or below the gate electrode 150, the source electrode 160 and/or the drain electrode 170, respectively, can have the same height. Meanwhile, lowermost surfaces of the gate insulating layer 140 under or below the gate electrode 150, the source electrode 160 and/or the drain electrode 170, respectively, can be coplanar or be at different heights. For example, the lowermost surface of the gate insulating layer 140 under or below the gate electrode 150 can be at a different level from those of the source electrode 160 and/or the drain electrode 170, respectively, but embodiments of the present disclosure are not limited thereto.

Hereinafter, a method of manufacturing a thin film transistor according to an embodiment of the present invention will be described.

According to an embodiment of the present invention, a method of manufacturing a thin film transistor can include a step of forming the light blocking layer 111 and the active layer 130 on the base substrate 110, a step of forming the low-reflective material layer 105 on the active layer 130, a step of forming the galvanic metal material layer 106 on the low-reflective material layer 105, a step of forming the photoresist material layer 109 on the galvanic metal material layer 106 and etching to expose a part of the light blocking layer 111 and a part of the active layer 130, a step of forming the first metal material layer 107 on the galvanic metal material layer 106, a step of forming the second metal material layer 108 on the first metal material layer 107, and a step of forming the gate electrode 150, the source electrode 160, and the drain electrode 170 by simultaneously etching the low-reflective material layer 105, the galvanic metal material layer 106, the first metal material layer 107, and the second metal material layer 108.

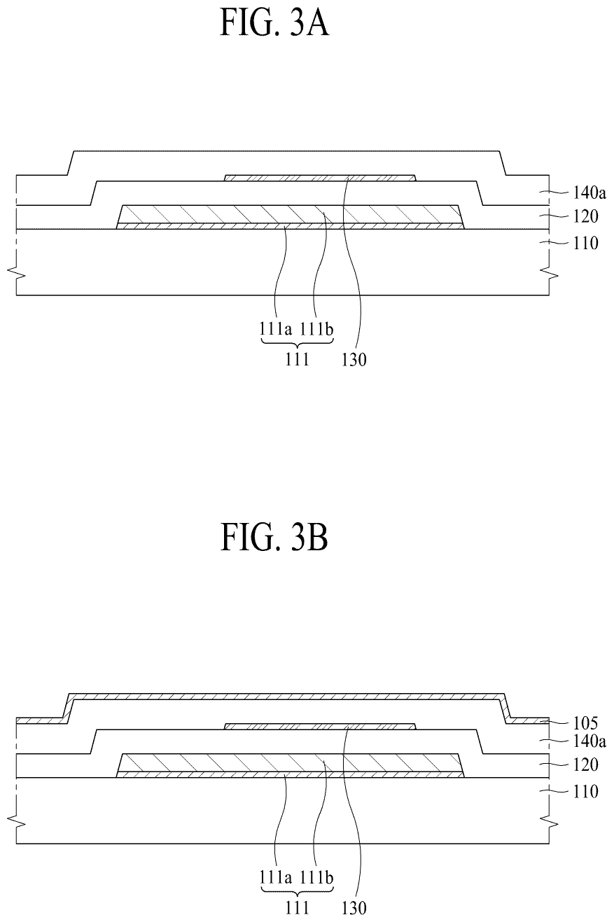

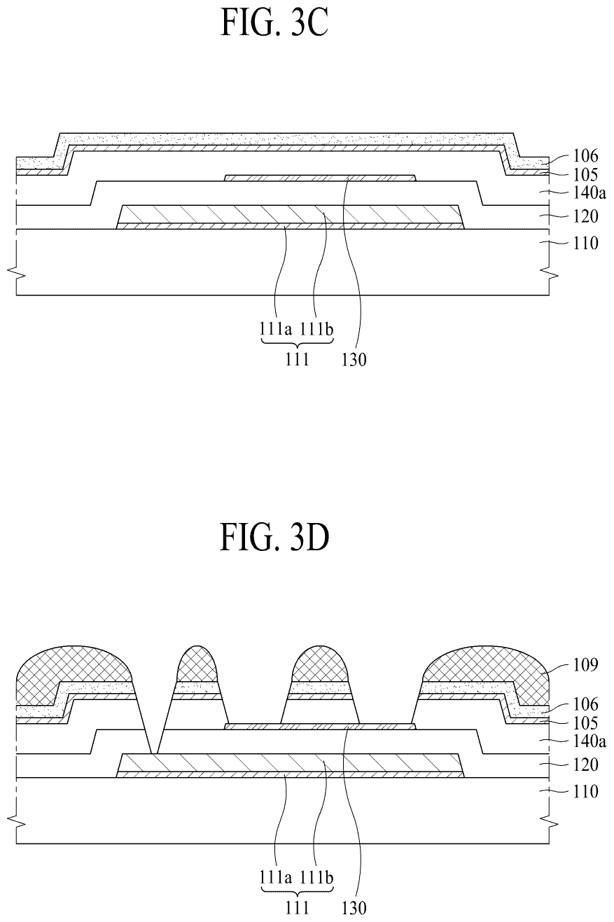

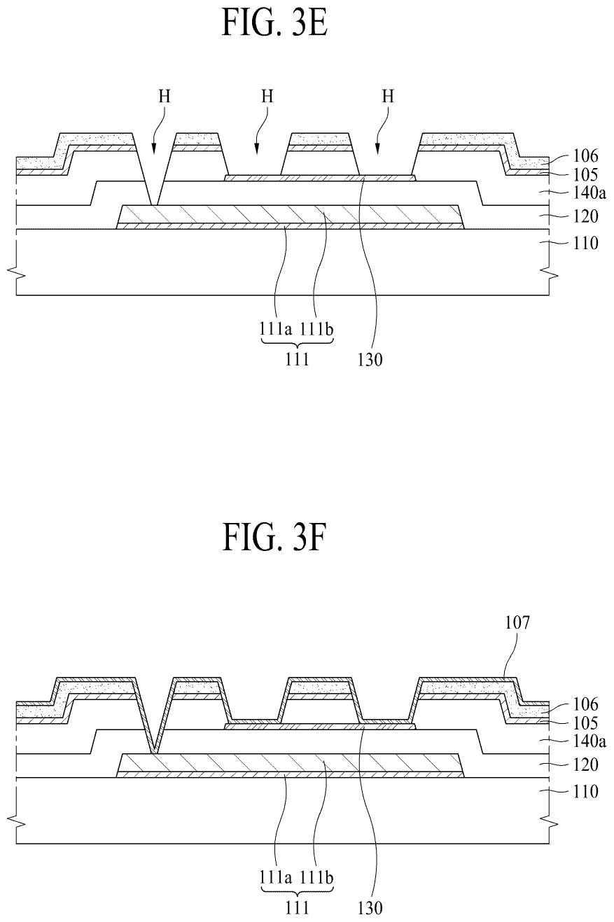

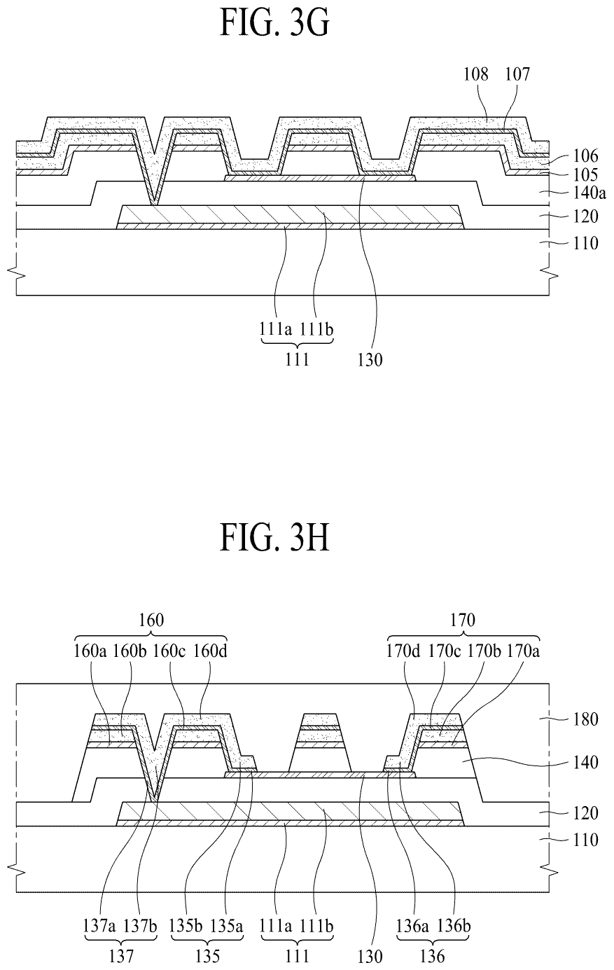

FIGS. 3A to 3H are process diagrams of a method of manufacturing a thin film transistor according to an embodiment of the present invention. Particularly, FIGS. 3A to 3H correspond to the cross-sectional view of FIG. 2.

Referring to FIG. 3A, a light blocking layer 111, a buffer layer 120, an active layer 130, and a gate insulating material layer 140a are sequentially stacked on the base substrate 110.

In this case, the light blocking layer 111 includes a first layer 111a and a second layer 111b. Descriptions thereof will be omitted in the above description.

Referring to FIG. 3B, the low-reflection material layer 105 is formed on the active layer 130. Specifically, the low-reflection material layer 105 is stacked on the gate insulation material layer 140a.

The low-reflective material layer 105 includes a low-reflective material. For example, the low-reflective material can include a metal oxide (MOx) containing the element M. In this case, the element M can include a group 6B element. But embodiments of the present disclosure are not limited thereto.

For example, the group 6B element can include at least one of chromium (Cr), molybdenum (Mo), and tungsten (W). But embodiments of the present disclosure are not limited thereto.

Referring to FIG. 3C, a galvanic metal material layer 106 is formed on the low-reflective material layer 105.

The galvanic metal material layer 106 includes a galvanic metal. For example, the galvanic metal can include at least one of Cu, Ag, Al, Mo, and Ti. But embodiments of the present disclosure are not limited thereto.

Referring to FIG. 3D, after forming the photoresist material layer 109 on the galvanic metal material layer 106, it can be etched to expose a part of the light blocking layer 111 and a part of the active layer 130.

Specifically, after the low-reflective material layer 105 and the galvanic metal material layer 106 are etched using wet etching, the contact hole H can be formed using dry etching. More specifically, a portion of the light blocking layer 111 and a portion of the active layer 130 can be exposed by wet etching and dry etching.

In this case, when the wet etching is performed in a state in which the galvanic metal material layer 106 is not disposed on the low-reflective material layer 105, a galvanic reaction may not occur, and a residual film of the low-reflective material layer can be formed due to limitations of the etchant. Subsequently, when dry etching is continuously performed, a spark-shaped residual film can be formed. As a result, such a residual film can cause occurrence of a defect and can cause a defect in disconnection.

In other words, there is no residual film left inside the thin film transistor, and in order to neatly form the contact hole H, it is necessary to continuously deposit the low-reflective material layer 105 and the galvanic metal material layer 106 and then perform wet etching and dry etching.

Referring to FIG. 3E, the photoresist material layer 109 disposed on the galvanic metal material layer 106 can be removed.

Referring to FIG. 3F, a first metal material layer 107 can be formed on the galvanic metal material layer 106. Specifically, the first metal material layer 107 can be formed not only on the galvanic metal material layer 106 but also on the side surface of the contact hole H shown in FIG. 3E, the exposed light blocking layer 111, and the active layer 130.

The first metal material layer 107 can include at least one selected from a metal and a transparent conductive oxide (TCO). For example, the metal can include a molybdenum-titanium alloy (MoTi), and the transparent conductive oxide (TCO) can include ITO (InSnO), IZO (InZnO), IO (InO), TO (SnO), and ZO (ZnO). But embodiments of the present disclosure are not limited thereto.

Referring to FIG. 3G, the second metal material layer 108 can be formed on the first metal material layer 107. Specifically, the second metal material layer 108 can be disposed on the entire surface of the first metal material layer 107.

The second metal material layer 108 can include a low resistance metal. For example, the low resistance metal can include at least one of Cu, Ag, Al, Mo, and Ti. But embodiments of the present disclosure are not limited thereto.

Referring to FIG. 3H, a gate electrode 150, a source electrode 160, and a drain electrode 170 can be formed by simultaneously etching the low-reflective material layer 105, the galvanic metal material layer 106, the first metal material layer 107, and the second metal material layer 108.

In this case, the formed gate electrode 150, source electrode 160, and drain electrode 170 include the first layers 150a, 160a, and 170a, the second layers 150b, 160b, and 170b on the first layers 150a, 160a, and 170b, the third layers 150c, 160c, and 170c on the second layers 150b, 160b, and the fourth layers 150d, 160d, and 170c on the third layers 150c, 160c, and 170c. The source electrode 160 and the drain electrode 170 are connected to the active layer 130 through the first contact portion 135 and the second contact portion 136, respectively.

In addition, the source electrode 160 is connected to the light blocking layer 111 through the third contact portion 137.

According to an embodiment of the present invention, a gate wiring extending from the gate electrode 150 can also form layers corresponding to the first and second layers 150a and 150b of the gate electrode 150, and a source wiring and a drain wiring extending from the source electrode 160 and the drain electrode 170 can also form layers corresponding to the first and second layers 160a and 170b and 170b of the source electrode 160 and the drain electrode 170. As a result, an increase in reflectance with respect to external light in the display apparatus can be suppressed.

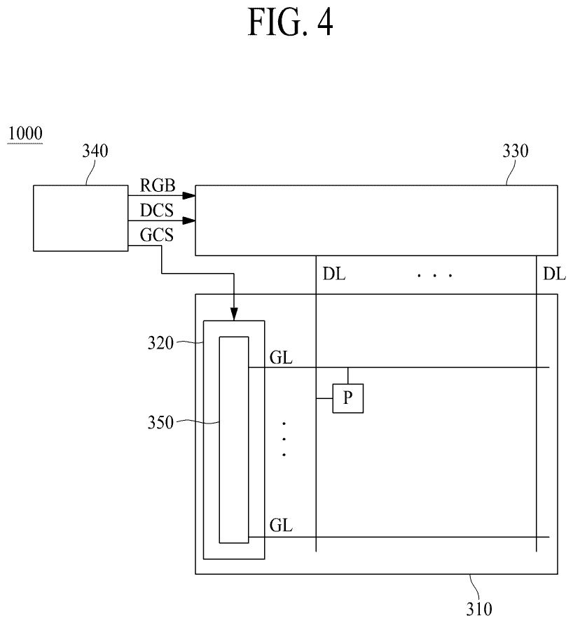

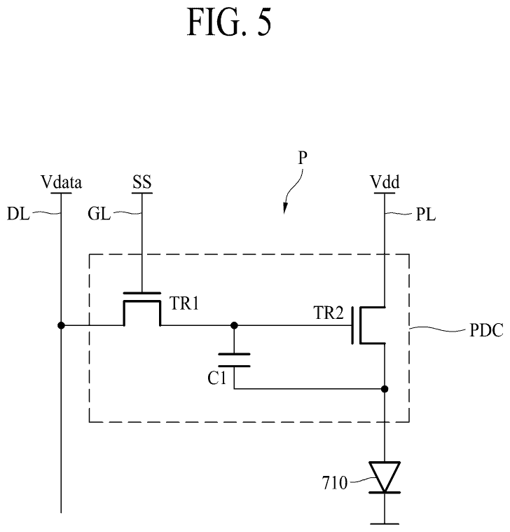

FIG. 4 is a schematic diagram illustrating a display apparatus 1000 according to further still another embodiment of the present disclosure.

Referring to FIG. 4, the display apparatus 1000 according to further still another embodiment of the present disclosure can include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P can be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Further, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Further, control signals for controlling a shift register can be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 can be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 can be disposed on the base substrate 110.

The display apparatus 1000 according to one embodiment of the present disclosure can include the above-described thin film transistors 100, and 200. According to one embodiment of the present disclosure, the gate driver 320 can include the above-described thin film transistors 100, and 200.

The gate driver 320 can include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Further, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 can include the above-described thin film transistors 100, and 200.

FIG. 5 is a circuit view illustrating any one pixel P of FIG. 4.

The circuit view of FIG. 5 is an equivalent circuit view for the pixel P of the display apparatus 1000 that includes an organic light emitting diode (OLED) as a display element 710.

Referring to FIG. 5, the pixel P includes a display element 710 and a pixel driving circuit PDC for driving the display element 710. In detail, the display apparatus 1000 according to one embodiment of the present disclosure can include a pixel driving circuit PDC on the base substrate 110.

The pixel driving circuit PDC of FIG. 5 includes a first thin film transistor TR1 that is a switching transistor and a second thin film transistor TR2 that is a driving transistor. The display apparatus 1000 according to another embodiment of the present disclosure can include at least one of the above-described thin film transistors 100, and 200.

The first thin film transistor TR1 is connected to the gate line GL and the data line DL and is turned on or off by the scan signal SS supplied through the gate line GL. In this case, the gate line GL and the data line DL can form layers corresponding to the first layers 150a, 160a, and 170a, the second layers 150b, 160b, and 170b, the third layers 150c, 160c, 170c, and the fourth layers 150d, 160d, and 170d of the gate electrode 150, the source electrode 160, and the drain electrode 170 according to an embodiment of the present invention. As a result, an increase in reflectance with respect to external light in the display device can be suppressed.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 can be controlled.

According to the present disclosure, the following advantageous effects can be obtained.

In the thin film transistor according to an embodiment of the present invention, since the source electrode and the drain electrode include a first layer including a low-reflective material and a second layer including a galvanic metal on the first layer, a residual film may not be generated during etching.

The thin film transistor according to an embodiment of the present invention can suppress or prevent an increase in reflectance by adjusting a multilayer structure having low reflection characteristics of a source electrode and a drain electrode, and can have characteristics of a low resistance wiring.

In addition to the above-mentioned effects, other features and advantages of the present invention can be described below, or can be clearly understood by those of ordinary skill in the art to which the present invention belongs from such techniques and descriptions.

In addition to the above-mentioned effects, other features and advantages of the present invention will be described below or clearly understood by those of ordinary skill in the art to which the present invention belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
a base substrate;
an active layer on the base substrate;
a gate electrode spaced apart from the active layer and overlapping at least a part of the active layer;
a source electrode connected to the active layer; and
a drain electrode spaced apart from the source electrode and connected to the active layer,
wherein each of the gate electrode, the source electrode, and the drain electrode includes:
a first layer including a low-reflective material;
a second layer disposed on the first layer and including a galvanic metal;
a third layer disposed on the second layer; and
a fourth layer disposed on the third layer, and
wherein the galvanic metal has a higher electron affinity than the low-reflective material.

2. The thin film transistor of claim 1, wherein the low-reflective material includes a metal oxide (MOx) including an element M, and
wherein the element M includes a group 6B element.

3. The thin film transistor of claim 2, wherein the group 6B element includes at least one of chromium (Cr), molybdenum (Mo), and tungsten (W).

4. The thin film transistor of claim 1, wherein the galvanic metal includes at least one of Cu, Ag, Al, Mo, and Ti.

5. The thin film transistor of claim 1, wherein the third layer includes at least one selected from a metal and a transparent conductive oxide (TCO).

6. The thin film transistor of claim 5, wherein the metal includes a molybdenum-titanium alloy (MoTi).

7. The thin film transistor of claim 1, wherein the fourth layer includes at least one of Cu, Ag, Al, Mo, and Ti.

8. The thin film transistor of claim 1, wherein each of the first layer of the source electrode, the first layer of the drain electrode, and the first layer of the gate electrode have a thickness of approximately 200 to 600 Å.

9. The thin film transistor of claim 1, wherein each of the source electrode and the drain electrode is connected to the active layer through a first contact portion and a second contact portion, and
wherein the first contact portion and the second contact portion include a first section and a second section on the first section of the first contact portion and the second contact portion, respectively.

10. The thin film transistor of claim 9, wherein the first section and the second section of the first contact portion are formed to extend from the third layer and the fourth layer of the source electrode, respectively, and
wherein the first section and the second section of the second contact portion are formed to extend from the third layer and the fourth layer of the drain electrode, respectively.

11. The thin film transistor of claim 9, wherein the active layer includes:
a channel area overlapping the gate electrode;
a source area connected to one side of the channel area; and
a drain area connected to the other side of the channel area, and
wherein the first contact portion is disposed on the source area and the second contact portion is disposed on the drain area.

12. The thin film transistor of claim 1, further comprising a light blocking layer on the base substrate,
wherein the source electrode is connected to the light blocking layer through a third contact portion.

13. The thin film transistor of claim 12, wherein the light blocking layer includes a first layer and a second layer on the first layer of the light blocking layer,
wherein the first layer of the light blocking layer includes the low reflective material, and
wherein the second layer of the light blocking layer includes a low resistance metal.

14. The thin film transistor of claim 12, wherein the third contact portion includes a first layer and a second layer on the first layer of the third contact portion,
wherein the first layer of the third contact portion is formed to extend from the third layer of the source electrode, and
wherein the second layer of the third contact portion is formed to extend from the fourth layer of the source electrode.

15. A display apparatus comprising the thin film transistor of claim 1.

16. A manufacturing method of a thin film transistor, the manufacturing method comprising:
forming a light blocking layer and an active layer on a base substrate;
forming a low-reflective material layer on the active layer;
forming a galvanic metal material layer on the low-reflective material layer;
forming a photoresist material layer on the galvanic metal material layer and etching to expose a portion of the light blocking layer and a portion of the active layer;
forming a first metal material layer on the galvanic metal material layer;
forming a second metal material layer on the first metal material layer; and
forming a gate electrode, a source electrode, and a drain electrode by simultaneously etching the low-reflective material layer, the galvanic metal material layer, the first metal material layer and the second metal material layer.

17. The manufacturing method of the thin film transistor of claim 16, wherein the low-reflective material layer includes the low-reflective material,
wherein the low-reflective material includes a metal oxide (MOx) containing a group 6B element.

18. The manufacturing method of the thin film transistor of claim 16, wherein the galvanic metal material layer includes at least one of Cu, Ag, Al, Mo, and Ti.

19. The manufacturing method of the thin film transistor of claim 16, wherein the first metal material layer includes at least one selected from a metal and a transparent conductive oxide (TCO),
wherein the second metal material layer includes at least one of Cu, Ag, Al, Mo, and Ti.

20. A thin film transistor comprising:
a base substrate;
an active layer on the base substrate;
a gate electrode spaced apart from the active layer and overlapping at least a part of the active layer;
a source electrode connected to the active layer; and
a drain electrode spaced apart from the source electrode and connected to the active layer,
wherein each of the gate electrode, the source electrode, and the drain electrode is separated from the base substrate by a gate insulating layer interposed between the base substrate and each of the gate electrode, the source electrode, and the drain electrode,
wherein each of the gate electrode, the source electrode, and the drain electrode includes:
a first layer including a metal oxide (MOx);
a second layer on the first layer and including a galvanic metal; and
a third layer disposed on the second layer, and including a conductive material, and
wherein an electron affinity of the second layer is higher than an electron affinity of the first layer.
